(19) United States
(12) Patent Application Publication
(10) Pub. No.: US 2025/0359239 A1
(43) Pub. Date: Nov. 20, 2025

(54) METHOD OF MANUFACTURING EPITAXIAL STRUCTURE AND EPITAXIAL STRUCTURE

(71) Applicant: GLOBALWAFERS CO., LTD., Hsinchu City (TW)

(72) Inventors: HONG-CHE LIN, Hsinchu City (TW); JIA-ZHE LIU, Hsinchu City (TW)

(73) Assignee: GLOBALWAFERS CO., LTD., Hsinchu City (TW)

(21) Appl. No.: 19/073,899

(22) Filed: Mar. 7, 2025

(30) Foreign Application Priority Data
May 20, 2024 (TW) 113118661

(51) Int. Cl. H10D 62/60; C30B 25/18; H10D 30/01; H10D 30/47

(52) U.S. Cl. CPC H10D 62/60; C30B 25/183; C30B 25/186; H10D 30/015; H10D 30/471

(57) ABSTRACT

A method of manufacturing an epitaxial structure includes: providing a substrate; forming a first buffer layer above the substrate; forming a roughened layer above the first buffer layer, wherein a process of forming the roughened layer includes performing a first low-temperature growth step and a high-temperature growth step; the first low-temperature growth step includes forming a first intrinsically doped structure at a first low-temperature; the high-temperature growth step includes forming an extrinsically doped structure at a high-temperature; the process of forming the roughened layer includes performing the first low-temperature growth step and the high-temperature growth step in sequence at least one time to form the roughened layer; the high-temperature is greater than the first low-temperature; forming a second buffer layer above the roughened layer; and forming a channel layer above the second buffer layer.

### BACKGROUND OF THE INVENTION

### Technical Field

The present invention relates generally to an epitaxial structure, and more particularly to a doped epitaxial structure.

### Description of Related Art

A high electron mobility transistor (HEMT) is typically a transistor having a two-dimensional electron gas (2-DEG) that is located close to a heterojunction of two materials with different energy gaps. As the HEMT makes use of the 2-DEG having a high electron mobility as a carrier channel of the transistor instead of a doped region, the HEMT has features of a high breakdown voltage, the high electron mobility, a low on-resistance, and a low input capacitance, thereby could be widely applied to high power semiconductor devices.

Generally, the HEMT is provided with a doped structure to improve the withstand voltage performance of the HEMT. However, a conventional doped structure has a problem of easily causing defects. Therefore, how to provide an epitaxial structure that enhances the withstand voltage performance and reduces defects, has become a major issue in the industry.

### BRIEF SUMMARY OF THE INVENTION

In view of the above, the primary objective of the present invention is to provide a method for manufacturing an epitaxial structure, which could provide an epitaxial structure having a good withstand voltage performance and a reduced number of defects.

The present invention provides a method of manufacturing an epitaxial structure, including: providing a substrate; form a first buffer layer above the substrate; forming a roughened layer above the first buffer layer, wherein a process of forming the roughened layer includes performing a first low-temperature growth step and a high-temperature growth step; the first low-temperature growth step includes forming a first intrinsically doped structure at a first low-temperature; the high-temperature growth step includes forming an extrinsically doped structure at a high-temperature; the process of forming the roughened layer includes performing the first low-temperature growth step and the high-temperature growth step in sequence at least one time to form the roughened layer; the high-temperature is greater than the first low-temperature; forming a second buffer layer above the roughened layer; and forming a channel layer above the second buffer layer.

In an embodiment, a difference between the high-temperature and the first low-temperature is greater than or equal to 50° C.

In an embodiment, the high-temperature is greater than or equal to 1000° C.; the first low-temperature is less than or equal to 980° C.

In an embodiment, the first low-temperature growth step includes forming the first intrinsically doped structure at a first low-temperature process pressure; the high-temperature growth step includes forming the extrinsically doped structure at a high-temperature process pressure; the high-temperature process pressure is greater than the first low-temperature process pressure.

In an embodiment, the high-temperature process pressure is greater than two times the first low-temperature process pressure.

In an embodiment, the high-temperature process pressure is greater than or equal to 150 torr; the first low-temperature process pressure is less than or equal to 75 torr.

In an embodiment, a thickness of the first intrinsically doped structure is greater than a thickness of the extrinsically doped structure.

In an embodiment, a thickness of the first intrinsically doped structure is between 2 times and 6 time the thickness of the extrinsically doped structure.

In an embodiment, a total thickness of the first intrinsically doped structure of the roughened layer is greater than or equal to 60% of a thickness of the roughened layer; the thickness of the roughened layer is greater than or equal to 600 nm and is less than or equal to 1000 nm.

In an embodiment, the method includes controlling an aluminum content of a part of the first buffer layer being in contact with the roughened layer to be less than or equal to 20%, wherein the roughened layer does not include aluminum.

In an embodiment, both a carbon doping concentration of the first intrinsically doped structure and a carbon doping concentration of the extrinsically doped structure are greater than or equal to 1E19 cm⁻³.

In an embodiment, the process of forming the roughened layer includes a second low-temperature growth step; the process of forming the roughened layer includes performing the first low-temperature growth step, the high-temperature growth step, and the second low-temperature growth step in sequence at least one time to form the roughened layer; the second low-temperature growth step includes forming a second intrinsically doped structure at a second low-temperature; the high-temperature is greater than a the second low-temperature.

In an embodiment, the second low-temperature growth step includes forming the second intrinsically doped structure at a second low-temperature process pressure; the high-temperature process pressure is greater than the second low-temperature process pressure.

In an embodiment, the first low-temperature is equal to the second low-temperature; the first low-temperature process pressure is equal to the second low-temperature process pressure.

In an embodiment, a total thickness of the first intrinsically doped structure and the second intrinsically doped structure of the roughened layer is greater than or equal to 80% of a thickness of the roughened layer; the thickness of the roughened layer is greater than or equal to 600 nm and is less than or equal to 1000 nm.

In an embodiment, a thickness of the second intrinsically doped structure is greater than or equal to a thickness of the extrinsically doped structure; a thickness of the first intrinsically doped structure is greater than or equal to the thickness of the second intrinsically doped structure.

In an embodiment, a carbon doping concentration of the second intrinsically doped structure is greater than or equal to 1E19 cm⁻³.

The present invention further provides an epitaxial structure, including a substrate, a first buffer layer, a roughened layer, a second buffer layer, and a channel layer. The first buffer layer is located above the substrate. The roughened layer is located above the first buffer layer. The roughened layer includes at least one doped structure. The at least one doped structure includes a first intrinsically doped structure and an extrinsically doped structure that are stacked. The second buffer layer is located above the roughened layer. The channel layer is located above the second buffer layer. An aluminum content of a part of the first buffer layer being in contact with the roughened layer is less than or equal to 20%. The roughened layer does not include aluminum. A doping concentration of the first intrinsically doped structure is greater than or equal to a doping concentration of the extrinsically doped structure.

In an embodiment, both a carbon doping concentration of the first intrinsically doped structure and a carbon doping concentration of the extrinsically doped structure are greater than or equal to 1E19 cm⁻³.

In an embodiment, a thickness of the first intrinsically doped structure is greater than or equal to a thickness of the extrinsically doped structure.

In an embodiment, a thickness of the first intrinsically doped structure is between 2 times and 6 times a thickness of the extrinsically doped structure.

In an embodiment, a total thickness of the first intrinsically doped structure of the roughened layer is greater than or equal to 60% of a thickness of the roughened layer; the thickness of the roughened layer is greater than or equal to 600 nm and is less than or equal to 1000 nm.

In an embodiment, the at least one doped structure includes a second intrinsically doped structure; the first intrinsically doped structure, the extrinsically doped structure, and the second intrinsically doped structure are stacked in sequence; a carbon doping concentration of the second intrinsically doped structure is greater than or equal to a carbon doping concentration of the extrinsically doped structure; the carbon doping concentration of the second intrinsically doped structure is greater than or equal to 1E19 cm⁻³.

In an embodiment, a total thickness of the first intrinsically doped structure and the second intrinsically doped structure of the roughened layer is greater than or equal to 80% of a thickness of the roughened layer; the thickness of the roughened layer is greater than or equal to 600 nm and is less than or equal to 1000 nm.

In an embodiment, a thickness of the second intrinsically doped structure is greater than or equal to a thickness of the extrinsically doped structure; a thickness of the first intrinsically doped structure is greater than or equal to the thickness of the second intrinsically doped structure.

With the aforementioned design, by performing the first low-temperature growth step and the high-temperature growth step in sequence at least one time to form the roughened layer, the epitaxial structure with a good epitaxial quality could be obtained, wherein the withstand voltage performance of the epitaxial structure could be enhanced and defects on a surface of the epitaxial structure could be reduced.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a flowchart of the method of manufacturing the epitaxial structure according to an embodiment of the present invention;

FIG. 2 is a schematic view of the epitaxial structure according to a first embodiment of the present invention;

FIG. 3 is a schematic view of the epitaxial structure according to another embodiment of the present invention;

FIG. 4 is a schematic view of the epitaxial structure according to a second embodiment of the present invention; and

FIG. 5 is a schematic view of the epitaxial structure according to another embodiment of the present invention.

### DETAILED DESCRIPTION OF THE INVENTION

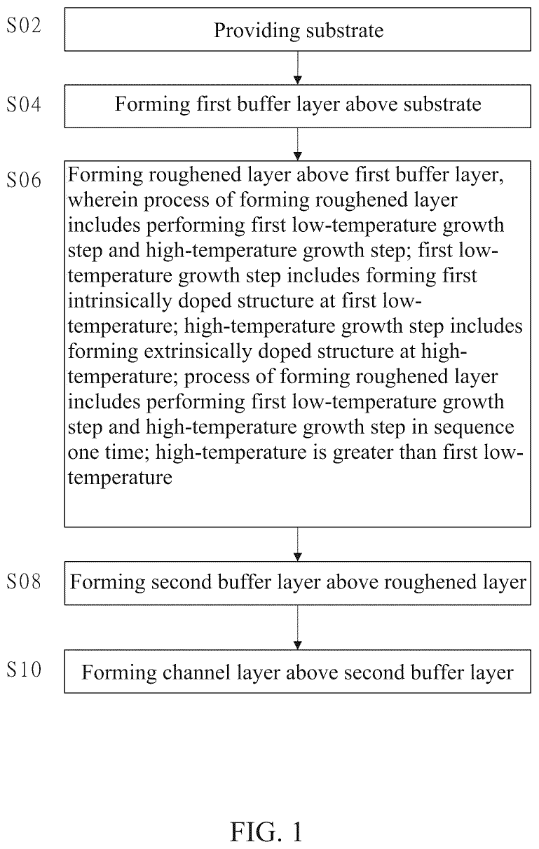

A flowchart of a method of manufacturing an epitaxial structure 1 according to a first embodiment of the present invention is illustrated in FIG. 1. The method of manufacturing the epitaxial structure 1 includes the following steps:

Step S02: providing a substrate 10; the substrate 10 could be, for example, a silicon substrate or a silicon carbide substrate.

Step S04: forming a first buffer layer 20 above the substrate 10; the first buffer layer 20 could be a layer including aluminum nitride, such as aluminum-gallium nitride (AlGaN). In step S04, the method further includes controlling an aluminum content of a surface of the first buffer layer 20 to be less than or equal to 20 at %.

In the current embodiment, the aluminum content of the surface of the first buffer layer 20 is equal to 10 at % as an example for illustration. A thickness T1 of the first buffer layer 20 is greater than or equal to 3 μm, thereby enhancing the withstand voltage performance. An aluminum content of the first buffer layer 20 could be gradually decreased from a part of the first buffer layer 20 being in contact with the substrate 10 to the surface of the first buffer layer 20 in a stepwise manner or a linear manner. Moreover, the first buffer layer 20 could be a single-layered structure, a multi-layered structure, a superlattice layer, or other structures.

Step S06: forming a roughened layer 30 above the first buffer layer 20, wherein a process of forming the roughened layer 30 includes performing a first low-temperature growth step and a high-temperature growth step; the first low-temperature growth step includes forming a first intrinsically doped structure 32 at a first low-temperature; the high-temperature growth step includes forming an extrinsically doped structure 34 at a high-temperature; the process of forming the roughened layer 30 includes performing the first low-temperature growth step and the high-temperature growth step in sequence one time to form the roughened layer 30; the high-temperature is greater than the first low-temperature. The roughened layer 30 does not include aluminum. In the current embodiment, the roughened layer 30 is a gallium nitride (GaN) layer.

A difference between the high-temperature and the first low-temperature is greater than or equal to 50° C. The high-temperature is greater than or equal to 1000° C. The first low-temperature is less than or equal to 980° C. Preferably, the first low-temperature is greater than or equal to 925° C. and is less than or equal to 975° C.

The first low-temperature growth step includes forming the first intrinsically doped structure 32 at a first low-temperature process pressure. The high-temperature growth step includes forming the extrinsically doped structure 34 at a high-temperature process pressure. The high-temperature process pressure is greater than the first low-temperature process pressure. The high-temperature process pressure is greater than 2 times the first low-temperature process pressure. The high-temperature process pressure is greater than or equal to 150 torr. The first low-temperature process pressure is less than or equal to 75 torr.

A thickness T2 of the first intrinsically doped structure 32 is greater than a thickness T3 of the extrinsically doped structure 34. The thickness T2 of the first intrinsically doped structure 32 is between 2 times and 6 times the thickness T3 of the extrinsically doped structure 34. In the current embodiment, the thickness T2 of the first intrinsically doped structure 32 is 5 times the thickness T3 of the extrinsically doped structure 34 as an example for illustration. A total thickness of the first intrinsically doped structure 32 of the roughened layer 30 is greater than or equal to 60% of a thickness T of the roughened layer 30. The thickness T of the roughened layer 30 is greater than or equal to 600 nm and is less than or equal to 1000 nm.

In the current embodiment, a doping element of the first intrinsically doped structure 32 and a doping element of the extrinsically doped structure 34 are carbon. No carbon source is additionally provided during forming the first intrinsically doped structure 32. A carbon source during forming the extrinsically doped structure 34 could be, for example, trimethylgallium (TMGa) or triethylgallium (TEGa). Both a carbon doping concentration of the first intrinsically doped structure 32 and a carbon doping concentration of the extrinsically doped structure 34 are greater than or equal to 1E19 cm⁻³. In the current embodiment, the carbon doping concentration of the first intrinsically doped structure 32 is 3E19 cm⁻³, and the carbon doping concentration of the extrinsically doped structure 34 is 1E19 cm⁻³ as an example for illustration.

Step S08: forming a second buffer layer 40 above the roughened layer 30. In the current embodiment, the second buffer layer 40 is a gallium nitride (GaN) layer that does not include aluminum. A thickness T4 of the second buffer layer 40 is greater than or equal to 1.5 μm. The second buffer layer 40 is formed at a temperature greater than 1000° C. and a pressure greater than or equal to 150 torr and less than or equal to 200 torr. An extrinsic carbon doping concentration of the second buffer layer 40 is greater than or equal to 1E19 cm⁻³ and is less than or equal to 3E19 cm⁻³.

Step S10: forming a channel layer 50 above the second buffer layer 40. The channel layer 50 could be a nitride channel layer, such as gallium nitride (GaN).

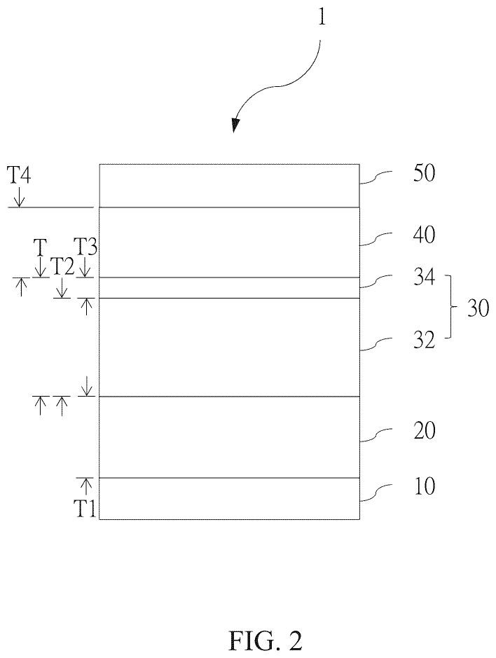

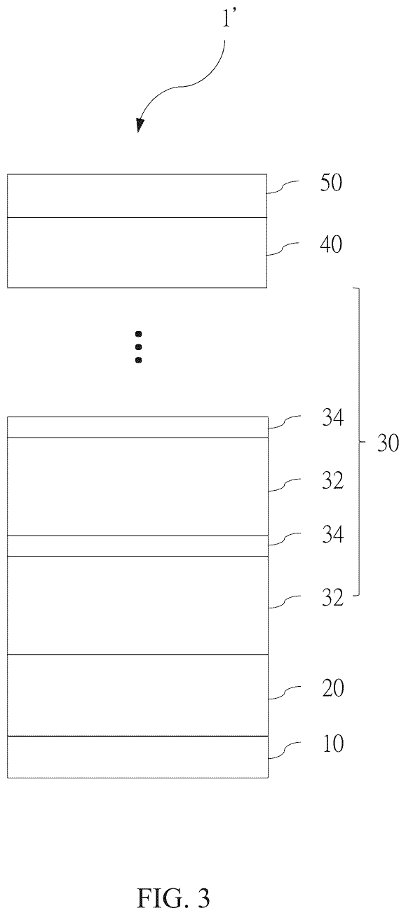

Moreover, in the current embodiment, the first low-temperature growth step and the high-temperature growth step are performed in sequence once to form the roughened layer 30 with the first intrinsically doped structure 32 and the extrinsically doped structure 34 that are stacked as an example (referring to FIG. 2). In another embodiment, an epitaxial structure 1′ is illustrated in FIG. 3, wherein the first low-temperature growth step and the high-temperature growth step are sequentially performed a plurality of times to form the roughened layer 30 with the first intrinsically doped structure 32 and the extrinsically doped structure 34 that are alternately stacked. The total thickness of the first intrinsically doped structure 32 of the roughened layer 30 is greater than or equal to 60% of the thickness T of the roughened layer 30. Preferably, the times for sequentially performing the first low-temperature growth step and the high-temperature growth step are between 2 and 4.

A method of manufacturing an epitaxial structure according to a second embodiment of the present invention is almost the same as the method of manufacturing the epitaxial structure in the first embodiment, except that in the second embodiment, the process of forming the roughened layer 30 further includes a second low-temperature growth step. The process of forming the roughened layer 30 includes performing the first low-temperature growth step, the high-temperature growth step, and the second low-temperature growth step in sequence once to form the roughened layer 30. The second low-temperature growth step includes forming a second intrinsically doped structure 32′ at a second low-temperature. The high-temperature is greater than the second low-temperature. The second low-temperature growth step includes forming the second intrinsically doped structure 32′ at a second low-temperature process pressure. The high-temperature process pressure is greater than the second low-temperature process pressure. The first low-temperature is equal to the second low-temperature. The first low-temperature process pressure is equal to the second low-temperature process pressure.

A total thickness of the first intrinsically doped structure 32 and the second intrinsically doped structure 32′ of the roughened layer 30 is greater than or equal to 80% of the thickness T of the roughened layer. The thickness T of the roughened layer 30 is greater than or equal to 600 nm and is less than or equal to 1000 nm. A thickness T2′ of the second intrinsically doped structure 32′ is greater than or equal to a thickness T3 of the extrinsically doped structure 34. A thickness T2 of the first intrinsically doped structure 32 is greater than or equal to a thickness T2′ of the second intrinsically doped structure 32′ A carbon doping concentration of the second intrinsically doped structure 32′ is greater than or equal to 1E19 cm⁻³.

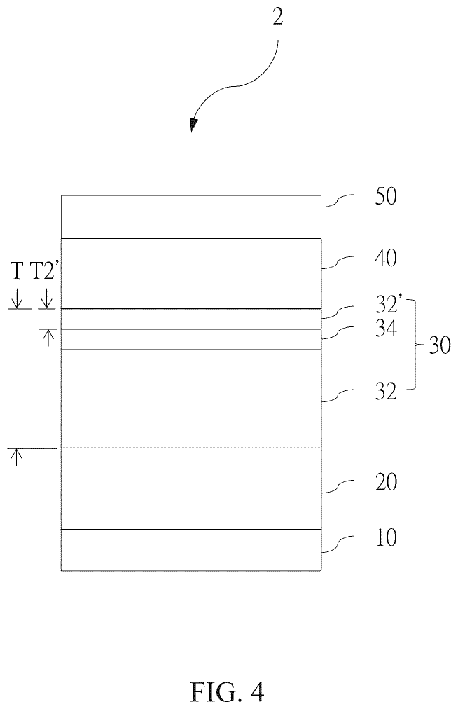

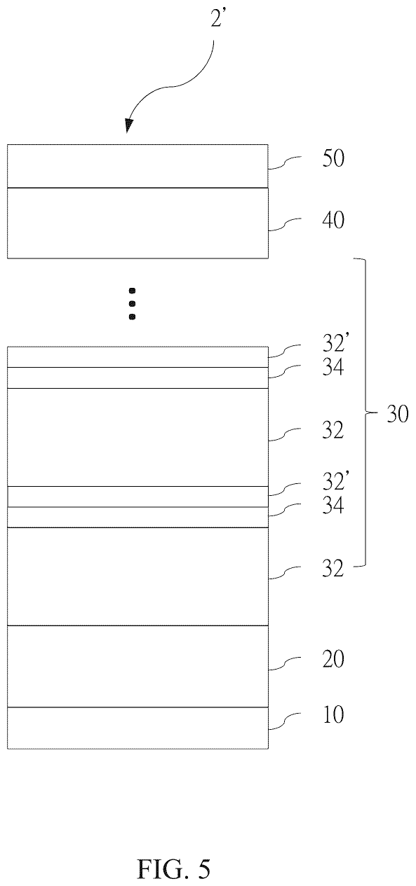

In the second embodiment, the first low-temperature growth step, the high-temperature growth step, and the second low-temperature growth step are performed in sequence once to form the roughened layer 30 with the first intrinsically doped structure 32, the extrinsically doped structure 34, and the second intrinsically doped structure 32′ that are stacked as an example (referring to FIG. 4). In another embodiment, an epitaxial structure 2′ is illustrated in FIG. 5, wherein the first low-temperature growth step, the high-temperature growth step, and the second low-temperature growth step are performed in sequence a plurality of times to form the roughened layer 30 with the first intrinsically doped structure 32, the extrinsically doped structure 34, and the second intrinsically doped structure 32′ that are alternately stacked. The total thickness of the first intrinsically doped structure 32 and the second intrinsically doped structure 32′ is greater than or equal to 80% of the thickness T of the roughened layer 30. Preferably, the time for sequentially performing the first low-temperature growth step, the high-temperature growth step, and the second low-temperature growth step is between 1 and 2.

The epitaxial structure 1 manufactured by the method of manufacturing the epitaxial structure of the first embodiment is illustrated in FIG. 2. The epitaxial structure 1 includes the substrate 10, the first buffer layer 20, the roughened layer 30, the second buffer layer 40, and the channel layer 50. The first buffer layer 20 is located above the substrate 10. The roughened layer 30 is located above the first buffer layer 20. The roughened layer 30 includes a doped structure. The doped structure includes the first intrinsically doped structure 32 and the extrinsically doped structure 34 that are stacked. The second buffer layer 40 is located above the roughened layer 30. The channel layer 50 is located above the second buffer layer 40. An aluminum content of a part of the first buffer layer 20 being in contact with the roughened layer 30 is less than or equal to 20%. The roughened layer 30 does not include aluminum. A doping concentration of the first intrinsically doped structure 32 is greater than or equal to a doping concentration of the extrinsically doped structure 34.

Referring to FIG. 3, in another embodiment, the roughened layer 30 could include a plurality of doped structures, i.e., a plurality of first intrinsically doped structures 32 and a plurality of extrinsically doped structures 34 that are stacked. Preferably, a number of the doped structures is between 2 and 4.

An epitaxial structure 2 manufactured by the method of manufacturing the epitaxial structure of the second embodiment is illustrated in FIG. 4. The epitaxial structure 2 includes the substrate 10, the first buffer layer 20, the roughened layer 30, the second buffer layer 40, and the channel layer 50. The first buffer layer 20 is located above the substrate 10. The roughened layer 30 is located above the first buffer layer 20. The roughened layer 30 includes the doped structure. The doped structure includes the first intrinsically doped structure 32 and the extrinsically doped structure 34 and further includes the second intrinsically doped structure 32′ stacked above the extrinsically doped structure 34. The second buffer layer 40 is located above the roughened layer 30. The channel layer 50 is located above the second buffer layer 40. An aluminum content of a part of the first buffer layer 20 being in contact with the roughened layer 30 is less than or equal to 20%. The roughened layer 30 does not include aluminum. A doping concentration of the first intrinsically doped structure 32 is greater than or equal to a doping concentration of the extrinsically doped structure 34. A carbon doping concentration of the second intrinsically doped structure 32′ is greater than or equal to a carbon doping concentration of the extrinsically doped structure 34.

Referring to FIG. 5, in another embodiment, the roughened layer could include a plurality of doped structures, i.e., a plurality of first intrinsically doped structures 32, a plurality of extrinsically doped structures 34, and a plurality of second intrinsically doped structures 32′ that are stacked. Preferably, a number of the doped structure is between 1 and 2.

The channel layer 50 of the epitaxial structures 1, 1′, 2, 2′ manufactured by the aforementioned method of manufacturing the epitaxial structure has the following features: an average number of defects with a diameter less than or equal to 0.3 um per square centimeter of a surface of the channel layer 50 is less than or equal to 2; an average number of defects with a diameter less than or equal to 0.2 um per square centimeter of the surface of the channel layer 50 is less than or equal to 1; an average number of defects with a diameter less than or equal to 0.1 um per square centimeter of the surface of the channel layer 50 is less than or equal to 0.5. The defects could be, for example, hexagonal defects, stacking faults, pit defects, or other common defects occurred in the epitaxial process, but the defects do not include defects formed by an external force, such as particles or scratches. Moreover, when the epitaxial structures 1, 1′, 2, 2′ are positively biased at 650V, a leakage current of the epitaxial structures 1, 1′, 2, 2′ is less than 3E-7 A/cm⁻².

With the aforementioned design, by performing the first low-temperature growth step and the high-temperature growth step in sequence at least one time to form the roughened layer 30, the epitaxial structure with a good epitaxial quality could be obtained, wherein the withstand voltage performance of the epitaxial structure could be enhanced and defects on a surface of the epitaxial structure could be reduced.

It must be pointed out that the embodiments described above are only some preferred embodiments of the present invention. All equivalent structures and methods which employ the concepts disclosed in this specification and the appended claims should fall within the scope of the present invention.

What is claimed is:

1. A method of manufacturing an epitaxial structure, comprising:
providing a substrate;
forming a first buffer layer above the substrate;
forming a roughened layer above the first buffer layer, wherein a process of forming the roughened layer comprises performing a first low-temperature growth step and a high-temperature growth step; the first low-temperature growth step comprises forming a first intrinsically doped structure at a first low-temperature; the high-temperature growth step comprises forming an extrinsically doped structure at a high-temperature; the process of forming the roughened layer comprises performing the first low-temperature growth step and the high-temperature growth step in sequence at least one time to form the roughened layer; the high-temperature is greater than the first low-temperature;
forming a second buffer layer above the roughened layer; and
forming a channel layer above the second buffer layer.

2. The method as claimed in claim 1, wherein a difference between the high-temperature and the first low-temperature is greater than or equal to 50° C.

3. The method as claimed in claim 1, wherein the high-temperature is greater than or equal to 1000° C.; the first low-temperature is less than or equal to 980° C.

4. The method as claimed in claim 1, wherein the first low-temperature growth step comprises forming the first intrinsically doped structure at a first low-temperature process pressure; the high-temperature growth step comprises forming the extrinsically doped structure at a high-temperature process pressure; the high-temperature process pressure is greater than the first low-temperature process pressure.

5. The method as claimed in claim 4, wherein the high-temperature process pressure is greater than two times the first low-temperature process pressure.

6. The method as claimed in claim 4, wherein the process of forming the roughened layer comprises a second low-temperature growth step; the process of forming the roughened layer comprises performing the first low-temperature growth step, the high-temperature growth step, and the second low-temperature growth step in sequence at least one time to form the roughened layer; the second low-temperature growth step comprises forming a second intrinsically doped structure at a second low-temperature; the high-temperature is greater than the second low-temperature.

7. The method as claimed in claim 6, wherein the second low-temperature growth step comprises forming the second intrinsically doped structure at a second low-temperature process pressure; the high-temperature process pressure is greater than the second low-temperature process pressure.

8. The method as claimed in claim 7, wherein the first low-temperature is equal to the second low-temperature; the first low-temperature process pressure is equal to the second low-temperature process pressure.

9. An epitaxial structure, comprising:
a substrate;
a first buffer layer, located above the substrate;
a roughened layer, located above the first buffer layer, wherein the roughened layer comprises at least one doped structure; the at least one doped structure comprises a first intrinsically doped structure and an extrinsically doped structure that are stacked;
a second buffer layer, located above the roughened layer; and
a channel layer, located above the second buffer layer;
wherein an aluminum content of a part of the first buffer layer being in contact with the roughened layer is less than or equal to 20%; the roughened layer does not include aluminum; a doping concentration of the first intrinsically doped structure is greater than or equal to a doping concentration of the extrinsically doped structure.

10. The epitaxial structure as claimed in claim 9, wherein both a carbon doping concentration of the first intrinsically doped structure and a carbon doping concentration of the extrinsically doped structure are greater than or equal to 1E19 cm⁻³.

11. The epitaxial structure as claimed in claim 9, wherein a thickness of the first intrinsically doped structure is greater than a thickness of the extrinsically doped structure.

12. The epitaxial structure as claimed in claim 9, wherein a thickness of the first intrinsically doped structure is between 2 times and 6 times a thickness of the extrinsically doped structure.

13. The epitaxial structure as claimed in claim 9, wherein a total thickness of the first intrinsically doped structure of the roughened layer is greater than or equal to 60% of a thickness of the roughened layer; the thickness of the roughened layer is greater than or equal to 600 nm and is less than or equal to 1000 nm.

14. The epitaxial structure as claimed in claim 9, wherein the at least on doped structure comprises a second intrinsically doped structure; the first intrinsically doped structure, the extrinsically doped structure, and the second intrinsically doped structure are stacked in sequence; a carbon doping concentration of the second intrinsically doped structure is greater than or equal to a carbon doping concentration of the extrinsically doped structure; the carbon doping concentration of the second intrinsically doped structure is greater than or equal to 1E19 cm⁻³.

15. The epitaxial structure as claimed in claim 14, wherein a total thickness of the first intrinsically doped structure and the second intrinsically doped structure of the roughened layer is greater than or equal to 80% of a thickness of the roughened layer; the thickness of the roughened layer is greater than or equal to 600 nm and is less than or equal to 1000 nm.

16. The epitaxial structure as claimed in claim 14, wherein a thickness of the second intrinsically doped structure is greater than or equal to a thickness of the extrinsically doped structure; a thickness of the first intrinsically doped structure is greater than or equal to the thickness of the second intrinsically doped structure.

17. The epitaxial structure as claimed in claim 9, wherein when the epitaxial structure is positively biased at 650V, a leakage current of the epitaxial structure is less than 3E-7 A/cm⁻².
